(19) United States
(12) Patent Application Publication
(10) Pub. No.: US 2022/0126908 A1
(43) Pub. Date: Apr. 28, 2022

(54) CONTROL DEVICE FOR A STEERING SYSTEM OF A MOTOR VEHICLE, ELECTROMECHANICAL POWER STEERING MECHANISM FOR A MOTOR VEHICLE AND STEER-BY-WIRE STEERING SYSTEM

(71) Applicants: thyssenkrupp Presta AG, Eschen (LI); thyssenkrupp AG, Essen (DE)

(72) Inventor: Gergely HORVATH, Fülöpszállás (HU)

(73) Assignees: thyssenkrupp Presta AG, Eschen (LI); thyssenkrupp AG, Essen (DE)

(21) Appl. No.: 17/436,874

(22) PCT Filed: Mar. 2, 2020
(86) PCT No.: PCT/EP2020/055458

§ 371 Date: Sep. 7, 2021

(30) Foreign Application Priority Data
Mar. 8, 2019 (DE) 10 2019 203 160.9

(51) Int. Cl. B62D 5/04; B62D 5/00

(52) U.S. Cl. CPC B62D 5/0406; B62D 5/0463; B62D 5/001

(57) ABSTRACT

A control unit for a steering system of a motor vehicle may include device electronics arranged on a circuit board. The device electronics can include control electronics, a power module, and a current feed. The control electronics are designed for processing input signals with output of control signals to the power module, and the power module has contact points for connection of a steering servo motor for actuating the steering servo motor based on the control signals. The circuit board is a rigid-flex circuit board with at least two rigid circuit carriers connected by at least one first flexible section. The control electronics and the power module are arranged on the circuit carriers, and a second flexible section of the circuit board is formed for the current feed on the circuit carrier of the power module.

The invention relates to a control unit for a steering system of a motor vehicle according to the generic term of claim 1, an electromechanical motor vehicle servo steering system according to the generic term of claim 8 and a steer-by-wire steering system according to the generic term of claim 9.

From DE 10 2009 002524 A1, a control unit is known for the operation of electric auxiliary or external power steering. Inside the control unit there is a circuit carrier on which a microcontroller is arranged for control and regulation purposes. Furthermore, there is an electronic power amplifier on the carrier, which is used to actuate an electric motor. The control unit is connected to the positive and negative poles of the battery by means of a battery plug-in system via corresponding contact points. The disadvantage is that the arrangement of the entire device electronics on a one-piece circuit carrier inside the control unit requires a lot of space. The result is correspondingly large control units.

Due to the constantly growing number of control units in motor vehicles, the installation space available for each control unit decreases while the vehicle size remains the same. One way to reduce the required installation space is to use several smaller circuit carriers and to connect them to each other when installed in the control unit and to arrange them in the control unit in a space-optimized manner. The disadvantage, however, is that the assembly of the control unit is made more difficult and the required plug connectors themselves take up a large proportion of the available installation space. In addition, a test of the hardware for component damage and faulty solder joints is only possible when assembled. A visual inspection in the assembled state is also time-consuming. These disadvantages complicate the cost-efficient use of multiboard systems in control units for steering systems.

It is therefore the object of the invention to create a control unit for a steering system of a motor vehicle, an electromechanical motor vehicle servo steering system and a steer-by-wire steering system which are small-scale and at the same time can be assembled quickly and easily.

This object is achieved by a control unit for a steering system of a motor vehicle with the features of claim 1, as well as by an electromechanical motor vehicle servo steering system with the features of claim 8 and a steer-by-wire steering system with the features of claim 9.

As a result of this, a control unit for a steering system of a motor vehicle is created with device electronics arranged on a printed circuit board. The device electronics include control electronics, a power module and a current feed. The control electronics are designed for processing input signals with the output of control signals to the power module. The power module has contact points for the connection of a steering servo motor for actuating the steering servo motor depending on the control signals received. With the control unit according to the invention, the circuit board is formed as a rigid-flex circuit board with at least two rigid circuit carriers connected by at least one first flexible section. The control electronics and the power module are accordingly arranged on each of the circuit carriers. A second flexible section of the circuit board is formed for the current feed on the circuit carrier of the power module.

By designing the circuit board as a rigid-flex circuit board, it is possible to arrange the entire device electronics of the control unit on a single circuit board and to install it in the control unit in a space-saving manner. This has the advantage that the device electronics can be fully tested for functionality before installation and visual inspection is also simplified. The installation of the circuit board in the control unit is simplified, as no plug connections have to be made between circuit boards. By connecting the rigid circuit carriers by means of at least one first flexible section, the circuit carriers can be installed in the control unit in a space-optimized manner.

A further advantage of the design according to the invention is the optimized current feed in the control unit. The arrangement of the power module on a separate rigid circuit carrier, which is designed in one piece with the current feed, allows the required high motor currents to be delivered directly to the steering servo motor without plug connections. In particular, the motor windings can be hardwired to the contact points of the power module. By shortening the current path, material costs are saved and ohmic losses are minimized. The power supply to the control electronics is carried out indirectly via the circuit carrier of the power module and the first flexible section. A separate power supply of the circuit carrier of the control electronics can thus be advantageously dispensed with. Due to the low power requirement of the control electronics compared to the motor currents, the extended current path for the control electronics is not significant.

Preferably, the two rigid circuit carriers are arranged at least partially overlapping one on top of the other in the control unit. This arrangement makes particularly good use of the installation space in the control unit. In particular, it may be provided that the rigid circuit carriers are essentially congruently one on top of the other.

In a preferred embodiment, the control unit can be attached to the steering servo motor as an extension of its motor shaft, wherein the circuit carrier of the power module is arranged on the motor side and the circuit carrier of the control electronics is arranged on the side of the circuit carrier of the power module facing away from the motor. Due to the arrangement of the power module on the motor side, the current path for the motor currents is shortened further.

Furthermore, it may be provided that the control electronics comprise a rotor position sensor and the circuit carrier of the power module has an aperture associated with the rotor position sensor for passing through an encoder element for the rotor position sensor. This embodiment is particularly advantageous when the control unit is arranged as an extension of the motor shaft of the steering servo motor. An encoder element attached to the motor shaft of the steering servo motor can be passed through the aperture of the circuit carrier of the power module provided on the motor side in order to interact with the rotor position sensor arranged on the circuit carrier of the control electronics. The rotor position sensor can thus be integrated directly into the control electronics without changing the optimized arrangement of the rigid circuit carriers in the control unit. Alternatively, a rotor position sensor may also be arranged on the circuit carrier of the power module or another separate rigid circuit carrier.

In a preferred embodiment, plug connectors, all of which are arranged on the circuit carrier of the control electronics, are further provided for reception of the input signals. Plug connectors must be particularly taken into account in the design of circuit carriers, as they take up considerable installation space both in the plane of the circuit carrier and in terms of height. By arranging all plug connectors for input signals of the control unit on the circuit carrier of the control electronics, the two rigid circuit carriers can be arranged particularly close to each other. The plug connectors are preferably arranged on the side of the circuit carrier facing away from the power module.

On the flexible section for the current feed, a third rigid circuit carrier may be formed on which a plug connector for connection to an on-board electrical system of the motor vehicle is arranged. The third rigid circuit carrier provides a fixed platform for the plug connector for the power supply, which can be anchored to the housing of the control unit. Alternatively, however, a plug connector may also be provided directly on the second flexible section.

The circuit carriers are preferably distanced from each other by spacer elements which are attached to the circuit carriers at fastening points which are associated with each other.

The invention further relates to an electromechanical vehicle servo steering system comprising a steering mechanism for the mechanical transmission of a driver's steering request from a steering wheel to steered wheels of the motor vehicle, a steering angle sensor for electronic detection of the driver's steering request and a steering servo motor for introducing a steering force assistance into the steering mechanism. For actuation of the steering servo motor depending on the driver's steering request detected by the steering angle sensor, the motor vehicle servo steering system comprises a previously described control unit according to the invention.

In a further embodiment, the invention relates to a steer-by-wire steering system comprising a steering angle sensor connected to a steering wheel via a steering shaft for the electronic detection of a driver's steering request, a feedback actuator and a steering servo motor for setting the detected driver's steering request on steered wheels. For actuating the steering servo motor depending on the driver's steering request detected by the steering angle sensor, the motor vehicle servo steering system comprises a previously described control unit according to the invention.

Further embodiments of the invention can be found in the following description and the subordinate claims.

The invention is explained in more detail below on the basis of the exemplary embodiments shown in the attached illustrations.

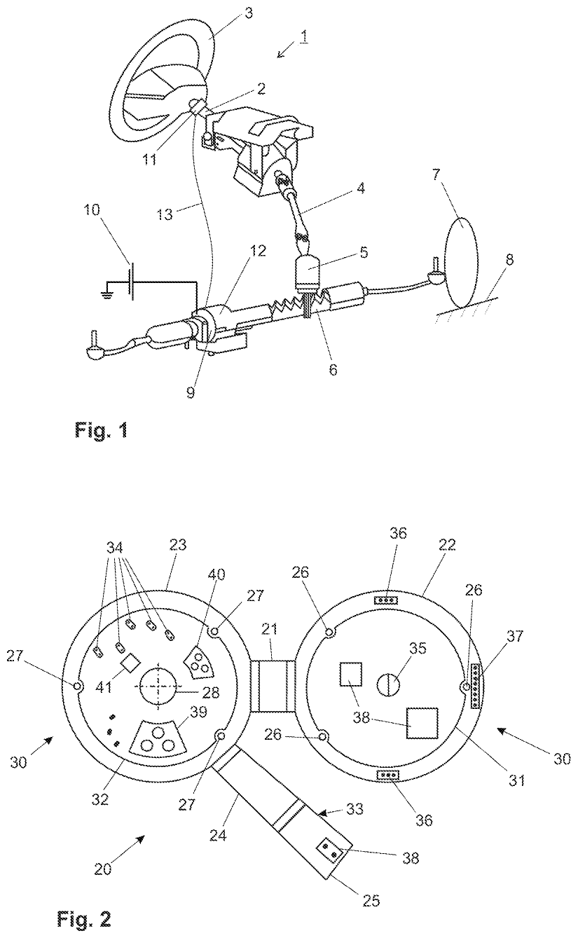

FIG. 1 shows schematically the structure of a steering system with an exemplary embodiment of a control unit according to the invention,

FIG. 2 shows schematically a top view of the circuit board of the control unit according to the exemplary embodiment according to FIG. 1 in the removed state,

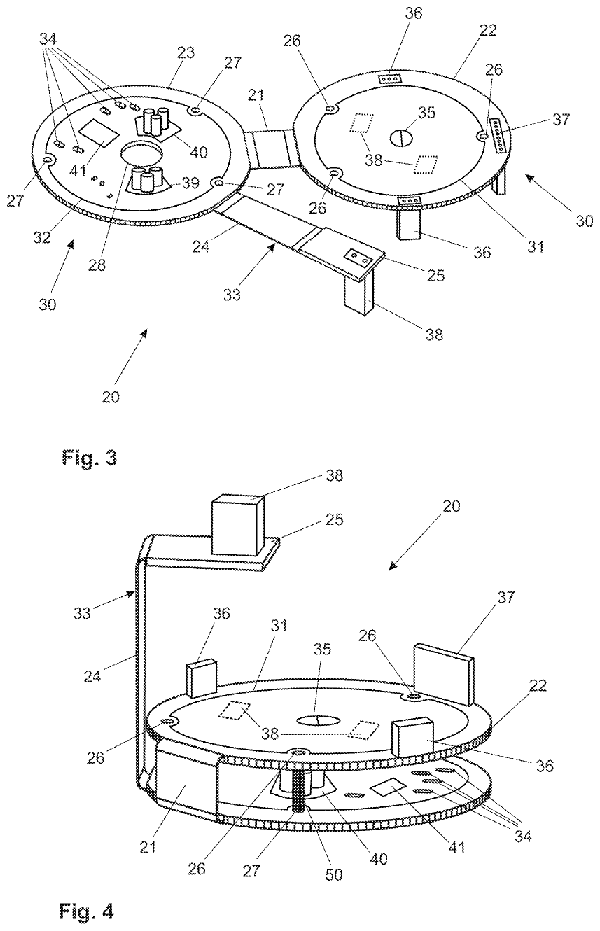

FIG. 3 shows schematically a perspective view of the circuit board of the control unit according to the exemplary embodiment according to FIG. 1 in the removed state,

FIG. 4 shows schematically a perspective view of the circuit board of the control unit according to the exemplary embodiment according to FIG. 1 in the installed state.

In FIG. 1 a steering system 1 of a motor vehicle with a control unit 9 according to the invention, which is used to actuate the steering system 1, is shown schematically. The steering system 1 has a steering wheel 3 attached to an upper steering shaft 2. The driver's steering request entered as the steering angle on the steering wheel 3 is transmitted via the upper steering shaft 2 and the lower steering shaft 4 to a steering gear 5, which converts the steering angle into a translation of a rack 6. The rack 6 is connected via tie rods to the steered wheels 7, which are in contact with the road 8. The steering wheel 3, steering shaft 2, 4, steering gear 5 and rack 6 thus form a steering mechanism for the mechanical transmission of a driver's steering request from the steering wheel 3 to the steered wheels 7 of the motor vehicle.

To provide steering force assistance, the steering system 1 further comprises a steering servo motor 12, which in the example shown is arranged axis-parallel to the rack 6 and drives a spindle drive for the longitudinal displacement of the rack 6. Alternatively, the steering servo motor may also be arranged, for example, in the area of the steering shaft 2, 4 and may introduce the steering force assistance on the steering shaft 2, 4 into the steering mechanism.

For actuating the steering servo motor 12, a control unit 9 is provided, which is flanged directly to the steering servo motor 12 as an extension of its motor shaft. The control unit 9 is connected to an electrical system battery 10 for the power supply. The control unit 9 is also connected to a steering angle sensor 11 via a signal line 13. The steering angle sensor 11 can be in the form, for example, of a rotation angle/torque sensor, which can detect not only the angle of rotation but also the torque of the steering wheel operation.

FIGS. 2 and 3 show the circuit board 20 of the control unit 9 according to FIG. 1 in the removed state. The entire device electronics 30 are arranged on the circuit board 20. The circuit board 20 is in the form of a rigid-flex circuit board. The circuit board has two rigid circuit carriers 22, 23 connected to a flexible section 21. The control electronics 31 are arranged on the circuit carrier 22 and the power module 32 of the control unit 9 is arranged on the circuit carrier 23. The power supply for the control electronics 31 and the transmission of control signals to the power module 32 can be carried out via the flexible section 21. A second flexible section 24 of the circuit board 20 is formed on the power module 32 as a current feed 33 for the control unit 9. In the exemplary embodiment shown, a third rigid circuit carrier 25 is formed in the second flexible section 24 for the current feed 33, on which a plug connector 38 for connection to an on-board electrical system of the motor vehicle is provided.

The on-board electrical system voltage is supplied directly to the power module 32 via the current feed 33. The power module 32 includes, for example, smoothing capacitors 39, which reduce the electromagnetic feedback of the inverter 41 used for motor actuation to the on-board electrical system. To actuate MOSFETs provided in the inverter 41, a gate-driver unit 40 is provided, which includes capacitors for recharging the gate electrodes of the MOSFETs. The contact points 34, to which the motor windings of the steering servo motor 12 can be connected, for example by soldering, are connected to the inverter 41.

The control electronics 31 of the control unit 9 can be structured multi-channel redundantly, for example. In the exemplary embodiment shown, the control electronics have two mutually independent signal processing channels. For this purpose, the control electronics 31 comprise two microprocessors 38 and two plug connectors 36 for the connection of a steering angle sensor 11 (which is of a dual redundant form). The control electronics 31 also include another plug connector 37 for connection to a motor vehicle bus system. Further input signals, such as the vehicle speed or an ignition signal for switching the control unit 9 on and off, can be provided via the bus system.

A rotor position sensor 35 is also arranged on the circuit carrier 22 of the control electronics 31. The rotor position sensor 35 is preferably also of an at least dual redundant form. On the circuit carrier 23 of the power module 32, an aperture 28 associated with the rotor position sensor 35 is provided for passing through an encoder element for the rotor position sensor 35. In the installed state (cf. FIG. 4), the rotor position sensor 35 is arranged above the aperture 28, so that an encoder element passed through the aperture 28 can interact directly with the rotor position sensor 35. The rotor position sensor 35 is preferably in the form of a magnetic or inductive sensor. A Hall sensor or an AMR sensor can be used as a magnetic sensor, for example.

Fastening points 26, 27 which are associated with each other may be provided on the circuit carriers 22, 23 for attaching spacer elements 50 (cf. FIG. 4), which distance the circuit carriers 22, 23 from each other. The shape of the circuit carriers 22, 23 is circular in the exemplary embodiment. However, any other circuit carrier shapes, for example square or polygonal, can also be selected.

FIG. 4 shows the circuit board 20 according to FIGS. 2 and 3 in the installed state. The flexible section 21 is bent in the installed state, preferably U-shaped, so that the rigid circuit carriers 22, 23 are arranged overlapping at least in sections one on top of the other in the control unit 9. In the example shown, the circuit carriers 22, 23 are essentially arranged parallel and congruent to each other.

In the installed state, the second flexible section 24 for the current feed 33 is preferably fed laterally past the circuit carrier 22 of the control electronics 31 to a connection side of the control unit 9. In the exemplary embodiment shown, a third rigid circuit carrier 25, on which a plug connector 38 for connection to an on-board electrical system of the motor vehicle is arranged, is formed on the flexible section 24 for the current feed 33. The connection for the power supply (in the example the plug connector 38) can be arranged above the circuit carrier 22. However, the flexibility of the flexible section 24 can also be used to arrange the connection for the power supply laterally, for example.

FIG. 4 shows the advantage of an arrangement of all plug connectors 36, 37 for input signals on the circuit carrier 22 of the control electronics 31. While the other installed electronic components, such as resistors, capacitors, coils and microprocessors, do not exceed installed heights of one or a few millimeters, plug connectors have installed heights of up to 1 to 2 cm. Due to the arrangement of the plug connectors on the upper circuit carrier 22, the circuit carriers 22, 23 can be arranged one on top of the other in a particularly space-saving manner. Due to the flexible section 21 for connecting the circuit carriers 22, 23, preferably only plug connectors for external components are required. The flexible section 21 thus allows additional freedom in the 3D design of the circuit carrier arrangement.

If the control unit 9 is attached to the steering servo motor 12 as an extension of its motor shaft as shown in FIG. 1, the circuit carrier 23 of the power module 32 is preferably arranged on the motor side and the circuit carrier 22 of the control electronics 31 is arranged on the side of the circuit carrier 23 of the power module 32 facing away from the motor in the control unit 9.

Although the invention in the preceding exemplary embodiment has been explained on the basis of an electromechanical motor vehicle servo steering system and a control unit for this, the control unit according to the invention can be used in the same way in a steer-by-wire steering system comprising a steering angle sensor connected to a steering wheel via a steering shaft for the electronic detection of a driver's steering request, a feedback actuator and a steering servo motor for setting the detected driver steering request on steered wheels for actuating the steering servo motor depending on the driver's steering request detected by the steering angle sensor.

The solution according to the invention creates a control unit that can be assembled particularly easily and in a space-saving manner and the device electronics can nevertheless be easily visually and electronically checked for errors before installation due to the arrangement on a single circuit board. In addition, the number of plug connectors is reduced to the necessary external plug connectors. Since the flexible sections only have to be shaped once during installation, the limited number of about 50 bending cycles of rigid-flex circuit boards does not represent a limiting factor in production. With regard to vibrations occurring during operation, the use of a rigid-flex circuit board is also advantageous, since the flexible sections (due to their small thickness of, for example, 0.2 mm) have only a negligible mass and thus provide a vibration-proof connection.

### REFERENCE CHARACTER LIST

1 steering system
2 upper steering shaft
3 steering wheel
4 lower steering shaft
5 steering gear
6 tie rods
7 wheels
8 road
9 control unit
10 electrical system battery
11 steering angle sensor
12 steering servo motor
13 signal line
20 circuit board
21 first flexible section
22, 23 circuit carriers
24 second flexible section
25 circuit carrier
26, 27 fastening points
28 aperture
30 device electronics
31 control electronics
32 power module
33 current feed
34 contact points
35 rotor position sensor
36, 37 plug connectors
38 microprocessor
39 smoothing capacitors
40 gate driver unit
41 inverter
50 spacer elements

1.-9. (canceled)

10. A control unit for a steering system of a motor vehicle, comprising:
a circuit board configured as a rigid-flex circuit board with at least two rigid circuit carriers connected by a first flexible section; and
device electronics arranged on the circuit board, the device electronics comprising control electronics, a power module, and a current feed, wherein the control electronics are configured for processing input signals with output of control signals to the power module, wherein the power module has contact points for connecting a steering servo motor for actuating the steering servo motor based on the control signals, wherein the control electronics and the power module are disposed on the at least two rigid circuit carriers, wherein a second flexible section of the circuit board is configured for a current feed on the rigid circuit carrier of the power module.

11. The control unit of claim 10 wherein the at least two rigid circuit carriers at least partially overlap one another.

12. The control unit of claim 10 configured for attachment to the steering servo motor as an extension of a motor shaft of the steering servo motor, wherein the rigid circuit carrier of the power module is disposed on a motor side, wherein the rigid circuit carrier of the control electronics is disposed on a side of the power module facing away from the steering servo motor.

13. The control unit of claim 10 wherein the control electronics comprise a rotor position sensor, wherein the rigid circuit carrier of the power module has an aperture associated with the rotor position sensor for feeding through an encoder element for the rotor positions sensor.

14. The control unit of claim 10 comprising plug connectors for receiving the input signals, wherein the plug connectors are disposed on the circuit carrier of the control electronics.

15. The control unit of claim 10 comprising a third rigid circuit carrier on which a plug connector is disposed for connection to an onboard electrical system of the motor vehicle, wherein the third rigid circuit carrier is disposed on the second flexible section for the current feed.

16. The control unit of claim 10 wherein the rigid circuit carriers are spaced apart by spacer elements that are attached to the rigid circuit carriers are mutually associated fastening points.

17. An electromechanical motor vehicle servo steering system comprising:
a steering mechanism for mechanical transmission of a driver's steering request from a steering wheel to steered wheels of a motor vehicle;
a steering angle sensor for electronic detection of the driver's steering request;
a steering servo motor for introducing steering force assistance into the steering mechanism; and
the control unit of claim 10 for actuating the steering servo motor based on the driver's steering request detected by the steering angle sensor.

18. A steer-by-wire steering system comprising:
a steering angle sensor connected to a steering wheel via a steering shaft for electronic detection of a driver's steering request;
a feedback actuator and a steering servo motor for setting the driver's steering request that has been detected on steered wheels; and
the control unit of claim 10 for actuating the steering servo motor based on the driver's steering request as detected by the steering angle sensor.
